(19) United States
(12) Patent Application Publication
(10) Pub. No.: US 2024/0282868 A1
(43) Pub. Date: Aug. 22, 2024

(54) DEVICE AND METHOD FOR IMPROVING THE OHMIC CONTACT BETWEEN A FRONT SIDE CONTACT AND A DOPED LAYER OF A WAFER SOLAR CELL

(71) Applicants: HANWHA Q CELLS GMBH, Bitterfeld-Wolfen (DE); CE Cell Engineering GmbH, Kabelsketal (DE)

(72) Inventors: Florian STENZEL, Bitterfeld-Wolfen (DE); Ansgar METTE, Bitterfeld-Wolfen (DE); Stefan HOERNLEIN, Bitterfeld-Wolfen (DE); Martin SCHAPER, Bitterfeld-Wolfen (DE); Axel SCHWABEDISSEN, Bitterfeld-Wolfen (DE); Janko CIESLAK, Bitterfeld-Wolfen (DE); Eckehard HOFMUELLER, Kabelsketal (DE); Stefan STOECKEL, Kabelsketal (DE); Eve KRASSOWSKI, Kabelsketal (DE)

(21) Appl. No.: 18/581,681

(22) Filed: Feb. 20, 2024

(30) Foreign Application Priority Data
Feb. 20, 2023 (DE) 102023104166.5

(51) Int. Cl. H01L 31/0224; H01L 31/16

(52) U.S. Cl. CPC H01L 31/022433; H01L 31/022441; H01L 31/165

(57) ABSTRACT

A device for improving the ohmic contact between a front side contact and a doped layer of a wafer solar cell that includes a front side, a rear side and a rear side contact. The front side and/or the rear side contact are strips or grids. The device includes: a contacting unit for contacting the front or rear side contact; a further contacting unit for contacting the other contact; a voltage source having one pole for connection to the contact unit and another pole for connection to the further contacting unit; and a point light source to illuminate the front or rear side. The further contacting unit includes: an optically transparent material, coated using an optically transparent, electrically conductive layer; or an optically transparent material having microscopically-thin wires; or an optically transparent, electrically conductive material having microscopically-thin wires; or a mesh or a network made up of microscopically-thin wires.

### PRIORITY CLAIM

The present application claims priority to German Patent Application No. 102023104166.5, filed on Feb. 20, 2023, which said application is incorporated by reference in its entirety herein.

### FIELD OF THE INVENTION

The invention relates to a device and a method for improving the ohmic contact between a front side contact and a doped layer of a wafer solar cell. A front side of the wafer solar cell represents the sun-facing side of the wafer solar cell during operation of the wafer solar cell, while a rear side of the wafer solar cell represents the sun-averted side of the wafer solar cell.

### BACKGROUND OF THE INVENTION

In dependence on the process control during the production of the wafer solar cell having the emitter layer in the form of a doped layer and the front side contact grid, high contact resistances can occur in some sections at the transition between a metal paste provided for creating the front side contact grid and the doped layer. Such excessively high contact resistances normally result in a reduced efficiency of the wafer solar cell.

Methods for improving the ohmic contact between the front side contact grid and the doped layer formed as emitter layer are known from DE 10 2016 009 560 A1 and DE 10 2018 001057 A1. Initially, a silicon wafer solar cell, having a doped layer provided for the function as emitter, a front side contact grid, and a rear contact is provided. The front side contact grid is then electrically connected to one pole of a voltage source and a contact unit electrically connected to the other pole of the voltage source is connected to the rear contact. A voltage directed opposite to the forward direction of the silicon wafer solar cell is applied using the voltage source, which is less in terms of absolute value than the breakthrough voltage of the silicon wafer solar cell. Upon application of the voltage, a point light source is guided over the sun-facing side of the silicon wafer solar cell. A segment of a partial area of the sun-facing side is illuminated and thus a current flow is locally induced in the partial area. This current flow, with respect to the segment, has a current density of 200 A/cm² to 20 000 A/cm² and acts for 10 ns to 10 ms on the partial area.

Local and subsequent improvement of the contact resistance of the wafer solar cell due to the application of the reverse voltage and the local illumination is achieved by the method. A high current flows here through a very small area and improves the metal semiconductor contact there. The wafer solar cell has to be contacted on both sides for application of the voltage. At the same time, the contact units also normally come to rest in the light path of the point light source, such that, no or only incomplete, processing takes place in the area of contact units, for example in the form of opaque bars.

FIG. 1 shows a cross-sectional view of a device known from the prior art according to DE 10 2016 009 560 A1. The wafer solar cell 1 has a front side 11 and a rear side 12. A front side contact 14 is arranged on the front side 11 and a rear side contact 15 is arranged on the rear side 12. The front side contact 14 and the rear side contact 15 are each in the form of strips or grids. The device furthermore has:
a contacting unit 3 for electrically contacting the front side contact 14, wherein the contacting unit 3 is designed in the form of four wires arranged in parallel, one of which is visible in section in FIG. 1,
a further contacting unit 2 for electrically contacting the rear side contact 15, wherein the further contacting unit 2 has an electrically conductive material which covers the entire surface of the rear side 12 during the electrical contacting and is optically non-transparent,
a voltage source 7 having one pole for electrical connection to the contact unit 3 and a further pole for electrical connection to the further contacting unit 2, and
a point light source 4 configured and designed to illuminate the front side 11 of the wafer solar cell 1.

In the associated method known from the prior art, the front side contact 14 is electrically contacted with the contacting unit 3 and the rear side contact 15 is electrically contacted with the further contacting unit 2. Furthermore, an electric voltage is applied by means of the voltage source 7 in order to generate a reverse current, and the point light source 4 is guided over the front side 11, such that a light beam 5 locally illuminates a partial section of the front side 11.

In this method, however, significant voltage losses occur in the path of the induced current via the front side contact 14. In addition, the contacting unit 3 in the form of the four wires shades the point light source 4 and includes the risk of damage to the wafer solar cell 1 due to the mechanical interaction. Furthermore, the wires can burn through due to local very high currents, which occur in the event of so-called shunts.

A further device according to the prior art is shown in cross section in a method for improving the ohmic contact between the front side contact grid and the doped layer of a wafer solar cell in FIGS. 2a to 2c. FIG. 2a shows a cross-sectional view of the device, which corresponds to the device shown in FIG. 1 with the difference that the contacting unit 3 does not have four wires, but rather has two electrically conductive opposing bars, and that the voltage source is not shown for the sake of clarity. As shown in FIG. 2a, one of the two electrically conductive bars contacts the front side contact 14, while the other of the two electrically conductive bars does not contact the front side contact 14, because the point light source 4 is guided over the partial section of the front side contact 14 and is moved over the front side of the wafer solar cell 1. Shading of the illuminated partial section is thus avoided. The other bar is then switched on opposite to the first in addition while the point light source 4 is guided over a middle partial section of the wafer solar cell 1. The one bar is then removed, such that in FIG. 2c, the point light source 4 can also process a partial section of the wafer solar cell 1, which is shaded by it in FIG. 2a. Significant voltage losses for the induced current in the course via the front side contact 14 up to the illuminated working point arise due to this type of electrical contacting. The current at the edge of the wafer solar cell 1 has to flow via the complete front side contact 14 to the opposite bar. The applied voltage at the illuminated working point is thus unevenly distributed over the area of the wafer solar cell 1 and the process thus cannot act homogeneously over the front side of the wafer solar cell 1. Furthermore, an electrically conductive bar is not redundant. As soon as a bar incompletely contacts the front side contact 14, the processing fails.

The shading of the wafer solar cell by the contacting units therefore results in problems. A part of the voltage drops because of resistance due to the solar cell contacts. A contact point close to the contacting unit therefore experiences different effective process parameters than a contact point far away from the contacting unit. The applied reverse voltage, which has a significant influence on the quality of the process, is thus inhomogeneous viewed over the front side of the wafer solar cell. This results in a wafer solar cell having reduced efficiency.

### SUMMARY OF THE INVENTION

It is an object of the invention to provide a device and a method for improving the ohmic contact between a front side contact and a doped layer of a wafer solar cell, by means of which the shading is prevented or at least reduced and a more homogeneous process control is possible in order to increase the efficiency of the wafer solar cell.

This object is achieved by a device having the features of devices and methods of the claims. Advantageous refinements and modifications are specified in the claims and will be explained hereinafter.

It is provided according to the invention that the further contacting unit has:
an optically transparent material which is coated using an optically transparent, electrically conductive layer, or
an optically transparent material having a multiplicity of microscopically thin electrically conductive wires, which are integrated into a surface of the optically transparent material, or
an optically transparent, electrically conductive material having a multiplicity of microscopically thin electrically conductive wires, which are integrated into a surface of the optically transparent, electrically conductive material, or
a mesh or a network made up of a multiplicity of microscopically thin electrically conductive wires.

The first variant of the further contacting unit is optically transparent over the entire surface and at the same time electrically conductive over the entire surface, such that negative effects due to shading and voltage losses up to the illuminated working point do not occur or are minimized. The further contacting unit is configured, designed and arranged for electrically contacting the front side contact or the rear side contact. A material which has a transmission of at least 90% in a spectrum having a wavelength range of 400 to 1500 nm is considered optically transparent in the meaning of the invention.

The further variants for forming the contacting unit include the use of microscopically thin electrically conductive wires. The feature of a microscopically thin wire presumes a wire diameter of less than a millimetre. These wires preferably have diameters of less than 500 μm, particularly preferably of less than 200 μm. At these wire diameters, the illuminated area of the point light source used is significantly larger than the diameter of the conductive wires. Due to the use of such thin wires, the correspondingly formed contacting units appear optically transparent upon macroscopic observation.

By means of the device and the method, an optically transparent or at least macroscopically optically transparent proof conductive over the entire area is provided for the electrical contact structures on the side of the wafer solar cell to be illuminated. The front or rear side contact of the wafer solar cell is thus electrically contacted and at the same time the corresponding solar cell surface, on which the contacting unit is arranged covering the surface, can be illuminated. The reverse current important for the LECO (Laser Enhanced Contact Optimization) effect has shorter and shorter paths in this way, such that the occurring voltage loss is minimized. In this way, any contact of the corresponding contact grid may be optimized under very similar process parameters. Moreover, the wafer solar cells can already be electrically contacted with the contacting units before the illumination, such that a sandwich made up of the wafer solar cell and the two contacting units can be illuminated without a time delay. Time is thus also saved during production.

In one preferred embodiment, the optically transparent material coated using an optically transparent, electrically conductive layer is formed as an optically transparent material in the form of glass or plastic coated using optically transparent conductive oxides. The electrically conductive oxides can be formed as TCO (transparent conductive oxides) such as ITO (indium-tin oxide) or ZnO:Al. Full-surface electrical contacting with the front or rear side contact may be achieved in this way, while at the same time the illumination of the side of the wafer solar cell electrically contacted with the further contacting unit is ensured.

The optically transparent material is preferably glass or a transparent plastic. The optically transparent, electrically conductive material is preferably formed from TCO, such as ITO or ZnO:Al.

The multiplicity of electrically conductive wires are preferably aligned parallel to one another and embedded as a grid or a mesh in the surface of the transparent material. Electrical contacting acting over the full surface with the front or rear side contact while ensuring a simultaneous transparency sufficient for the illumination of the point light source is also ensured in this way.

In one preferred embodiment, the multiplicity of microscopically thin, electrically conductive wires are formed from metal and/or from a metal alloy. The multiplicity of microscopically thin, electrically conductive wires are preferably formed from semiprecious and/or precious metals, for example in the form of metal threads as silver, gold, or copper threads.

The front side contact and the rear side contact preferably each have contact fingers arranged parallel to one another having a contact finger width oriented parallel to the surface of the wafer solar cell and perpendicular to an extension direction of the contact fingers. The microscopically thin, electrically conductive wires of the multiplicity of wires preferably each have a width less than the contact finger width. Minimized shading is thus still ensured.

The point light source can be, for example, a laser, a light-emitting diode, or focused radiation of a flash lamp. The point light source preferably emits radiation having wavelengths in the range from 400 nm to 1500 nm. The point light source is preferably a laser, in particular a laser diode.

The invention furthermore relates to a method for improving the ohmic contact between a front side contact and a doped layer of a wafer solar cell using the device according to one or more of the above-described embodiments, comprising the following steps:
a) electrically contacting the front side contact using the contacting unit or the further contacting unit,
b) electrically contacting the rear side contact using the other of the contacting unit or the further contacting unit,
c) applying a voltage directed opposite to the forward direction of the wafer solar cell by means of the voltage source on the front side contact and the rear side contact, wherein the applied voltage is less in terms of absolute value than the breakthrough voltage of the wafer solar cell,
d) guiding the point light source during the application of the voltage over the sun-facing front side when the further contacting unit electrically contacts the front side contact or over the sun-averted rear side of the wafer solar cell when the further contacting unit electrically contacts the rear side contact, wherein a segment of a partial section of the sun-facing front side or of the sun-averted rear side is illuminated such that a current flow is induced in the partial section and acts on the partial section.

In one preferred embodiment, steps a) to d) are carried out in a stationary manner in the device. The method is suitable for stationary performance and for treating individual wafer solar cells.

However, the device is preferably formed as a component of an in-line production system for wafer solar cells. Steps a) and b) comprise loading the contacting unit and the further contacting unit with the wafer solar cell, for example from a loading belt. The wafer solar cell is transported between steps b) and d) using the contact unit and/or the further contact unit as a transport unit for the wafer solar cell from a loading/contacting zone of the device, in which steps a) and b) are carried out, to an illumination zone, in which steps c) and d) are carried out, and then to an unloading zone, in which the contacting unit and the further contacting unit are spatially separated from the wafer solar cell. The wafer solar cell is unloaded here, for example, onto an unloading belt.

A cycle time for the method is reduced.

The contacting unit and the further contacting unit of the device designed as part of an in-line production system are preferably moved together with contacted wafer solar cells in an in-line transport cycle from the loading/contacting zone through the illumination zone to the unloading zone and in a back-transport loop back to the loading/contacting zone again. The two contacting units are thus guided in a circulating system or method. After the unloading, they are returned outside the process area for renewed loading. The cycle time may thus be further significantly reduced. Instead of contacting, processing, and unloading the wafer solar cell in one cycle, these steps are separated. Each step is carried out in one cycle.

The method is preferably carried out using the following parameters: a voltage is applied by means of the voltage source to the front side contact grid and the rear side contact grid against the forward direction which is in the range of 1 to 40 V. The local illumination preferably has a power density which is in the range of 200 to 500 000 W/cm². The method is preferably carried out such that a current of 0.1 to 10 A flows between the front side and rear side contacts.

The provided wafer solar cell preferably has a contact resistance >50 mOhmcm² before the performance of the method according to the invention, measured using the TLM method (transfer length method). In one preferred embodiment, the provided wafer solar cell has a contact area of less than 0.1% before the performance of the method according to the invention. That is to say, the metallized surface of the metal semiconductor contacts corresponds to less than 0.1% of the surface on which the metal semiconductor contacts are located. The provided wafer solar cell preferably has one or more passivation and/or antireflection layers. The antireflection layer preferably has a thickness of greater than 100 nm. The antireflection layer is formed, for example, from SiNₓ (silicon nitride). The antireflection layer can also be formed as an SiNₓ(silicon nitride)/SiOₓN_{y} (silicon oxynitride) double layer or SiNₓ(silicon nitride)/SiOₓN_{y} (silicon oxynitride)/SiO₂ (silicon dioxide) triple layer having thicknesses of greater than 100 or greater than 110 nm. The provided wafer solar cell preferably has a higher layer resistance of the doped layer on the front side than on the rear side.

The wafer solar cell subjected to the method can be a single solar cell, a multiple solar cell, or a partial cell of a multiple solar cell.

### BRIEF DESCRIPTION OF THE FIGURES

Further advantages and properties of the method will be explained on the basis of the preferred embodiments described hereinafter. The figures are not shown to scale and are therefore to be understood as purely schematic and by way of example.

Schematically and not to scale:

FIG. 1 shows a cross-sectional view of a device according to the prior art;

FIGS. 2a-2c each show a cross-sectional view of a further device according to the prior art which carries out a method according to the prior art;

FIG. 3 shows a cross-sectional view of a device according to a first embodiment, which carries out a step of the method according to the invention;

FIG. 4 shows a cross-sectional view of a device according to a second embodiment, which carries out a step of the method according to the invention;

FIG. 5 shows a cross-sectional view of a device according to a third embodiment, which carries out a step of the method according to the invention;

FIG. 6 shows a cross-sectional view of a device according to a fourth embodiment, which carries out a step of the method according to the invention; and

FIG. 7 shows a perspective view of a device according to a fifth embodiment, which carries out a method according to the invention.

### DETAILED DESCRIPTION

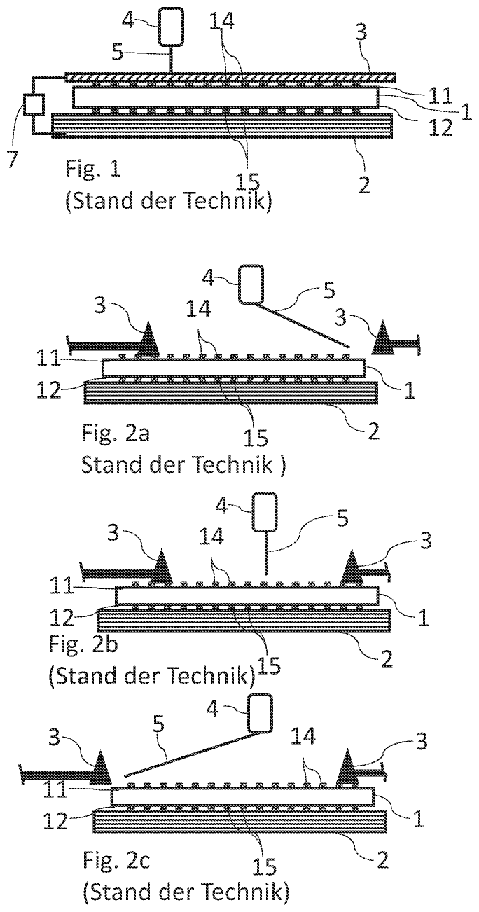

FIG. 1 shows a cross-sectional view of a device according to the prior art and FIGS. 2a-2c each show a cross-sectional view of a further device according to the prior art, which carries out a method known from the prior art. Reference is made to the above statements on these figures in the introductory part of the description.

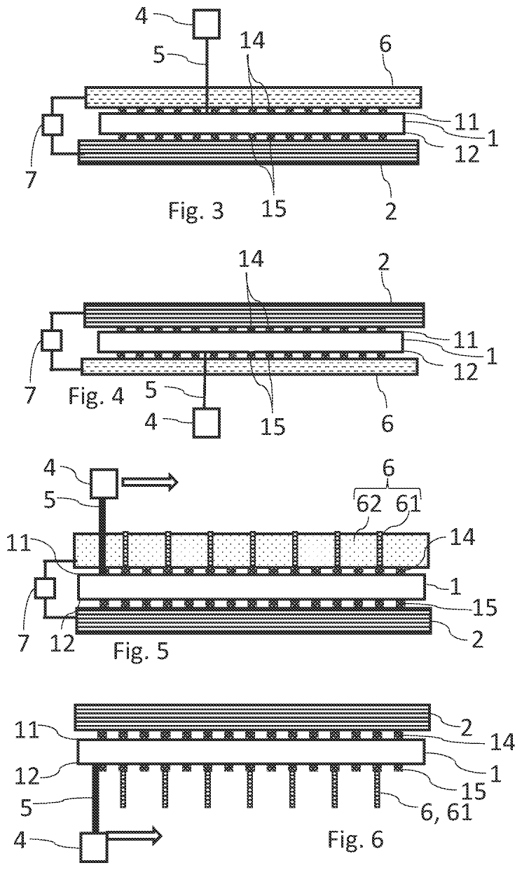

FIG. 3 shows a cross-sectional view of a device according to a first embodiment, which carries out a step of the method according to the invention. The device shown in FIG. 3 corresponds to the device shown in FIG. 1 with the difference that instead of the contacting unit 3, it has the further contacting unit 6, which comprises an optically transparent material that is coated using an optically transparent, electrically conductive layer. The point light source 4 illuminates the front side 11 locally using a light beam 5, during the application of an electric voltage directed opposite to the forward direction of the wafer solar cell 1 by means of the voltage source 7, the contacting unit 2, and the further contacting unit 6 on the front side contact 14 and the rear side contact 15, wherein the applied voltage is less in terms of absolute value than the breakthrough voltage of the wafer solar cell 1.

FIG. 4 shows a cross-sectional view of a device according to a second embodiment, which carries out a step of the method according to the invention. The device shown in FIG. 4 corresponds to the device shown in FIG. 3 with the difference that the contacting unit 2 electrically contacts the front side contact 14 while the further contacting unit 6 electrically contacts the rear side contact 15, and the point light source 4 is arranged and designed to locally illuminate the rear side 12 using the light beam 5.

FIG. 5 shows a cross-sectional view of a device according to a third embodiment, which carries out a step of the method according to the invention. The device shown in FIG. 5 corresponds to the device shown in FIG. 3 with the difference that the further contacting unit 6 comprises an optically transparent material 62 having a multiplicity of microscopically thin, electrically conductive wires 61, which are integrated into a surface of the optically transparent material 62. During the generation of the reverse current, the point light source 4 is guided in the arrow direction over the front side 11. The optically transparent material 62 can in one variant also be an optically transparent, electrically conductive material.

FIG. 6 shows a cross-sectional view of a device according to a fourth embodiment, which carries out a step of the method according to the invention. The device shown in FIG. 6 corresponds to the device shown in FIG. 4 with the difference that the further contacting unit 6 comprises a mesh or a network made up of a multiplicity of microscopically thin, electrically conductive wires 61 and that the voltage source is not shown for the sake of clarity. During the generation of the reverse current, the point light source 4 is guided in the arrow direction over the rear side 12.

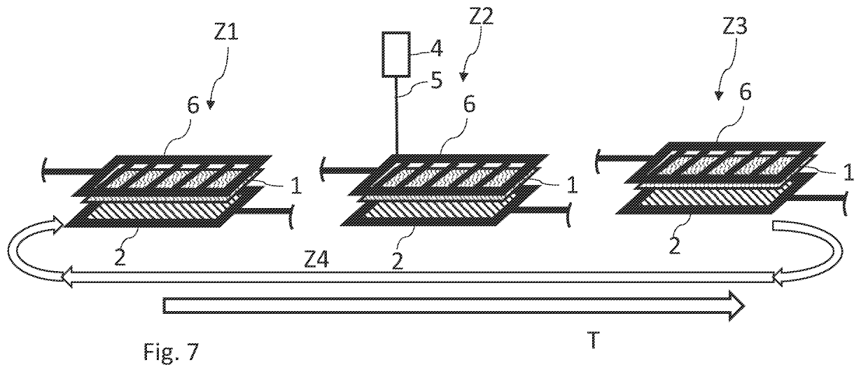

FIG. 7 shows a perspective view of a device according to a fifth embodiment, which carries out a method according to the invention. The device is designed as part of an in-line production system for wafer solar cells 1. It is used to improve the ohmic contact between a front side contact (not shown in FIG. 6) and a doped layer (not shown), formed for example as an emitter layer, of a wafer solar cell 1, which comprises the front side contact, the doped layer, and a rear side contact (not shown in FIG. 6), wherein the front side contact is formed in the form of strips or grids. The device has a contacting unit 2 for electrically contacting the rear side contact and a further contacting unit 6 for electrically contacting the front side contact. It also has a voltage source (not shown in FIG. 6) having one pole for electrical connection to the contact unit 2 and a further pole for electrical connection to the further contacting unit 6 and a point light source 4, which is configured and designed to illuminate the front side of the wafer solar cell 1 using a light beam 5. The further contacting unit 6 has an optically transparent material which is coated using an optically transparent, electrically conductive layer or an optically transparent material (not shown) having a multiplicity of microscopically thin, electrically conductive wires (not shown), which are integrated into a surface of the optically transparent material, or a mesh or a network made up of a multiplicity of microscopically thin, electrically conductive wires (not shown). It furthermore has a loading/contacting zone Z1, an illumination zone Z2, an unloading zone Z3, and a back-transport loop Z4.

In the loading/contacting zone Z1, the contacting unit 2 and the further contacting unit 6 are loaded with the wafer solar cell 1 and the front side contact is electrically contacted with the further contacting unit 6, and the rear side contact is electrically contacted with the contacting unit 2. The sandwich consisting of the wafer solar cell 1 with the two contacting units 2, 6 is then transported using the contact unit 2 and/or the further contact unit 6 as transport means for the wafer solar cell 1 from the loading/contacting zone Z1 to the illumination zone Z2. In the illumination zone Z2, a voltage directed against the forward direction of the wafer solar cell 1 is applied by means of the voltage source to the front side contact and the rear side contact, wherein the applied voltage is less in terms of absolute value than the breakthrough voltage of the wafer solar cell 1, and during application of the voltage, the point light source 4 is guided over the front side, wherein a segment of a partial section of the front side is illuminated such that a current flow is induced in the partial section and acts on the partial section. In a subsequent step, the sandwich is transported to the unloading zone Z3, in which the contacting unit 2 and the further contacting unit 6 are spatially separated from the wafer solar cell 1. The contacting unit 2 and the further contacting unit 6 are then moved in the back-transport loop Z4 back to the loading/contacting zone Z1, to be loaded again here.

The contacting units 6 are moved together with contacted wafer solar cells 1 in an in-line transport cycle from the loading/contacting zone Z1 through the illumination zone Z2 to the unloading zone Z3 and by the back-transport loop Z4 back to the loading/contacting zone Z1 again, and so a circulation system suitable for in-line mass production is provided.

### LIST OF REFERENCE SIGNS

T transport direction
Z1 loading/contacting zone
Z2 illumination zone
Z3 unloading zone
Z4 back-transport loop
1 wafer solar cell
11 front side
12 rear side
14 front side contact
15 rear side contact
2 contacting unit
3 wire
4 point light source
5 light beam
6 further contacting unit
61 wire
62 transparent material
7 voltage source

1. A device for improving the ohmic contact between a front side contact and a doped layer of a wafer solar cell, the wafer solar cell comprising a front side, a rear side, the front side contact, the doped layer and a rear side contact, wherein the front side contact and/or the rear side contact is or are in the form of strips or grids, the device comprising:
a contacting unit for electrically contacting one of the front side or rear side contacts;
a further contacting unit for electrically contacting the other of the rear side or front side contacts;
a voltage source having one pole for electrical connection to the contact unit and another pole for electrical connection to the further contacting unit;
a point light source configured and designed to illuminate the front side or the rear side of the wafer solar cell;
wherein:
the further contacting unit comprises:
an optically transparent material, which is coated using an optically transparent, electrically conductive layer; or
an optically transparent material having a multiplicity of microscopically thin, electrically conductive wires, which are integrated into a surface of the optically transparent material; or
an optically transparent, electrically conductive material having a multiplicity of microscopically thin, electrically conductive wires which are integrated into a surface of the optically transparent, electrically conductive material; or
a mesh or a network made up of a multiplicity of microscopically thin, electrically conductive wires.

2. The device according to claim 1, wherein the optically transparent material coated using an optically transparent, electrically conductive layer is formed as an optically transparent material in the form of glass or plastic coated using optically transparent conductive oxides.

3. The device according to claim 1, wherein the multiplicity of microscopically thin, electrically conductive wires are aligned in parallel to one another and embedded as a grid or as a mesh in the surface of the transparent material.

4. The device according to claim 1, wherein the multiplicity of microscopically thin, electrically conductive wires are formed from metal and/or a metal alloy, preferably from semiprecious and/or precious metals.

5. The device according to claim 4, wherein the multiplicity of microscopically thin, electrically conductive wires are formed from semiprecious and/or precious metals.

6. The device according to claim 1, wherein the front side contact and the rear side contact have contact fingers are arranged parallel to one another and have a contact finger width oriented parallel to a surface of the wafer solar cell and perpendicular to an extension direction of the contact fingers, and the wires of the multiplicity of microscopically thin, electrically conductive wires each have a width less than the contact finger width.

7. A method for improving the ohmic contact between a front side contact and a doped layer of a wafer solar cell using a device according to claim 1, comprising the following steps:
a) electrically contacting the front side contact using the contacting unit or the further contacting unit;
b) electrically contacting the rear side contact using the other of the contacting unit or the further contacting unit;
c) applying a voltage directed against the forward direction of the wafer solar cell using the voltage source to the front side contact and the rear side contact, wherein the applied voltage is less in terms of absolute value than a breakthrough voltage of the wafer solar cell;
d) guiding the point light source during application of the voltage over the sun-facing front side, when the further contacting unit electrically contacts the front side contact, or over the sun-averted rear side of the wafer solar cell, when the further contacting unit electrically contacts the rear side contact, wherein a segment of a partial section of the sun-facing front side or of the sun-averted rear side is illuminated such that a current flow is induced in the partial section and acts on the partial section.

8. The method according to claim 7, wherein steps a) to d) are carried out in a stationary manner in the device.

9. The method according to claim 7, wherein the device is designed as part of an in-line production system for wafer solar cells and steps a) and b) comprise loading the contacting unit and the further contacting unit with the wafer solar cell, and the wafer solar cell is transported between steps b) and d) using the contact unit and/or the further contact unit as a transport unit for the wafer solar cell from a loading/contacting zone of the device, in which steps a) and b) are carried out, to an illumination zone, in which steps c) and d) are carried out, and then to an unloading zone, in which the contacting unit and the further contacting unit are spatially separated from the wafer solar cell.

10. The method according to claim 9, wherein the contacting unit and the further contacting unit of the device designed as part of an in-line production system are moved together with contacted wafer solar cells in an in-line transport cycle from the loading/contacting zone through the illumination zone to the unloading zone and in a back-transport loop back to the loading/contacting zone again.
